(19) United States
(12) Patent Application Publication
(10) Pub. No.: US 2025/0268012 A1
(43) Pub. Date: Aug. 21, 2025

(54) WINDOW MODULE AND ELECTRONIC DEVICE INCLUDING THE SAME

(71) Applicant: SAMSUNG DISPLAY CO., LTD., YONGIN-SI (KR)

(72) Inventors: BYOUNG DAE YE, Yongin-si (KR); SOOJIN SUNG, Yongin-si (KR)

(21) Appl. No.: 18/984,564

(22) Filed: Dec. 17, 2024

(30) Foreign Application Priority Data
Feb. 19, 2024 (KR) 10-2024-0023838

(51) Int. Cl. H10H 29/854; H10K 59/80

(52) U.S. Cl. CPC H10H 29/854; H10K 59/873

(57) ABSTRACT

A window module includes a window film, high refractive index patterns disposed on the window film and having a first refractive index and arranged side by side, and low refractive index patterns disposed between the high refractive index patterns and having a second refractive index that is less than the first refractive index.

### CROSS-REFERENCE TO RELATED APPLICATION

This application claims priority under 35 U.S.C. § 119 to Korean Patent Application No. 10-2024-0023838, filed on Feb. 19, 2024, the content of which in its entirety is herein incorporated by reference.

### TECHNICAL FIELD

The present disclosure relates to an electronic device and, more specifically, to a window module and an electronic device including the window module.

### DISCUSSION OF THE RELATED ART

A display device is an electronic device for displaying stationary and/or moving images. Display devices often include a display panel for generating the image and a window disposed on the display panel to protect the display panel from exposure and damage. The window may, however, reduce display quality, particularly where the window may be subject to reflection. Thus, structures that can reduce the reflectance of the display device are being developed.

### SUMMARY

A window module includes a window film, high refractive index patterns disposed on the window film, each of the high refractive index patterns having a first refractive index, and being arranged side by side. Low refractive index patterns are disposed between neighboring pairs of the high refractive index patterns, the low refractive index patterns having a second refractive index that is smaller than the first refractive index.

The first refractive index may be within a range of about 1.5 to about 1.8. The second refractive index may be within a range of about 1.3 to about 1.5.

Each of the low refractive index patterns may include a binder and an inorganic particle dispersed within the binder.

A refractive index of the binder may be greater than the second refractive index.

A difference between the first refractive index and a refractive index of the binder may be less than a difference between the first refractive index and the second refractive index.

The inorganic particle may be a hollow silica particle.

A pitch between neighboring pairs of the high refractive patterns may be about 0.5 μm or more.

A bisector line bisecting the high refractive index patterns in a thickness direction thereof may be defined, and a sum of areas of the high refractive patterns located at a lower part of the bisector line may be greater than a sum of areas of the high refractive patterns located at an upper part of the bisector line.

A shape of each of the high refractive index patterns may be triangular.

A lower surface of the triangular shape may be disposed adjacent to the window film.

A shape of each of the high refractive index patterns may be trapezoidal.

A length of a lower surface of the trapezoidal shape may be longer than a length of an upper surface of the trapezoidal shape, and the lower surface of the trapezoidal shape may be disposed adjacent to the window film.

The high refractive index patterns may contact each other.

The high refractive index patterns may be spaced apart from each other.

An electronic device includes a display panel, and a window module disposed on the display panel. The window module includes a window film, high refractive index patterns disposed on the window film, each of the high refractive index patterns having a first refractive index, and being arranged side by side. Low refractive index patterns are disposed between neighboring pairs of the high refractive index patterns and each having a second refractive index that is smaller than the first refractive index.

The display panel may include pixel electrodes arranged side by side, and a pitch between the pixel electrodes may be different from a pitch between the high refractive index patterns.

The first refractive index may be within a range of about 1.5 to about 1.8, and the second refractive index may be within a range of about 1.3 to about 1.5.

Each of the low refractive index patterns may include a binder, and an inorganic particle dispersed within the binder.

A refractive index of the binder may be greater than the second refractive index, and a difference between the first refractive index and a refractive index of the binder may be less than a difference between the first refractive index and the second refractive index.

A bisector line bisecting the high refractive index patterns in a thickness direction thereof may be defined, and a sum of areas of the high refractive patterns located at a lower part of the bisector line may be greater than a sum of areas of the high refractive patterns located at an upper part of the bisector line.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view illustrating a display device according to an embodiment of the present invention;

FIG. 2 is a block diagram illustrating a display panel included in the display device of FIG. 1;

FIG. 3 is a circuit diagram illustrating a pixel included in the display panel of FIG. 2;

FIG. 4 is a cross-sectional view illustrating the display panel of FIG. 2;

FIG. 5 is a cross-sectional view illustrating the display device of FIG. 1;

FIG. 6 is a graph illustrating a reflectance according to a wavelength of light of display device of FIG. 5;

FIG. 7 is a cross-sectional view illustrating a display device according to an embodiment of the present invention;

FIG. 8 is a cross-sectional view illustrating a display device according to an embodiment of the present invention; and

FIG. 9 is a block diagram illustrating an electronic device according to an embodiment.

### DETAILED DESCRIPTION

In describing embodiments of the present disclosure illustrated in the drawings, specific terminology is employed for sake of clarity. However, the present disclosure is not necessarily intended to be limited to the specific terminology so selected, and it is to be understood that each specific element includes all technical equivalents which operate in a similar manner.

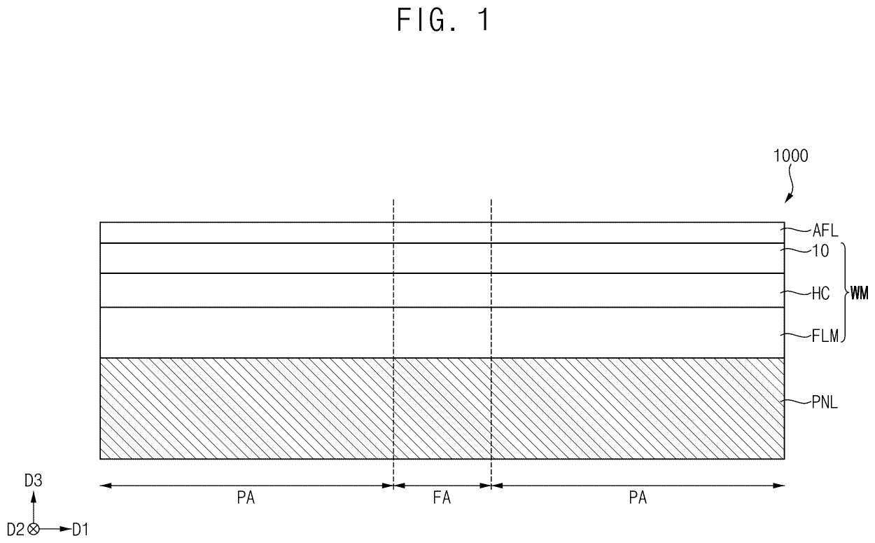

FIG. 1 is a cross-sectional view illustrating a display device according to an embodiment of the present invention.

Referring to FIG. 1, a display device 1000, according to an embodiment of the present invention, may include a display panel PNL, a window module WM, and an anti-fingerprint layer AFL. The window module WM may include a window film FLM, a hard coating layer HC, and a refractive layer 10. In addition, the display device 1000 may further include a touch panel, an adhesive layer, a lower support pattern made of metal, a lower cushion layer, etc.

In an embodiment, the display device 1000 may be a foldable display device, for example, a display panel that may be folded to a noticeable extent without cracking or otherwise sustaining damage. The display device 1000 may be divided into a folding area FA and a flat area PA, and may be folded in the folding area FA and not folded within the flat area FA. Accordingly, the window module WM may be appropriately flexible for folding.

In an embodiment, the display device 1000 may be implemented as a rigid display device, a curved display device, or a rollable display device.

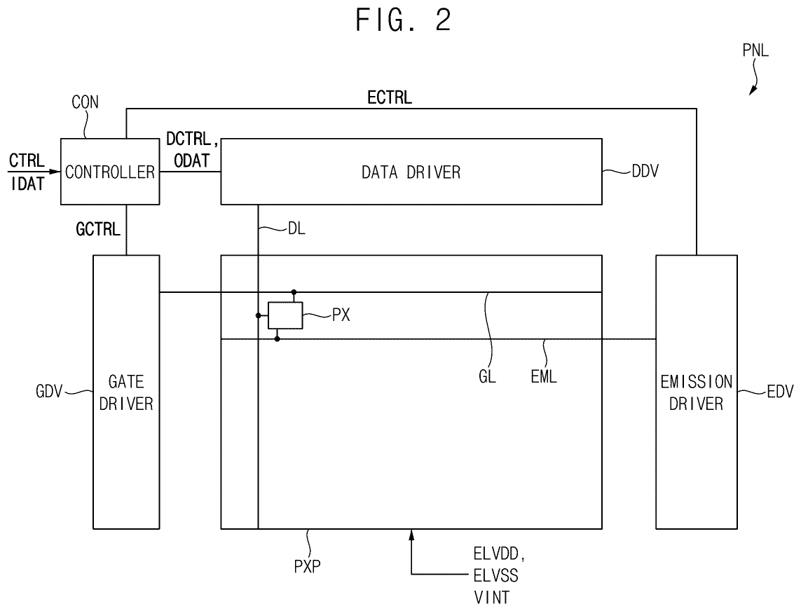

The display panel PNL may emit light. The display panel PNL will be described with reference to FIGS. 2 to 4.

The window film FLM may be disposed on the display panel PNL. In an embodiment, the window film FLM may include glass, quartz, plastic, etc.

Examples of glass that can be used as the window film FLM may include ultra-thin tempered glass (UTG). Examples of plastics that can be used as the window film FLM may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), etc. These can be used alone or in combination with each other.

The hard coating layer HC may be disposed on the window film FLM. The hard coating layer HC may have a higher degree of hardness than the window film FLM, for example, as measured in the Mohs scale or as measured by a test such as Brinell, Vickers, or Rockwell. In an embodiment, the hard coating layer HC may include a urethane-based resin, an epoxy-based resin, an acrylic-based resin, and/or an acrylate-based resin. In addition, the thickness of the hard coating layer HC may be set within a range that does not increase the repulsion force while the display device 1000 is folded.

The refractive layer 10 may be disposed on the hard coating layer HC. The refractive layer 10 may prevent reflection of external light. For example, the upper refractive index and the lower refractive index of the refractive layer 10 may be different from each other, and accordingly, a phase shift may be formed between the light reflected at the upper boundary of the refractive layer 10 and the light reflected at the lower boundary of the refractive layer 10. As destructive interference occurs based on the phase shift, the refractive layer 10 may prevent reflection of external light.

The anti-fingerprint layer AFL may be disposed on the refractive layer 10. In an embodiment, the anti-fingerprint layer AFL may be formed by coating an anti-fingerprint material on the refractive layer 10. Examples of anti-fingerprint materials that can be used as the anti-fingerprint layer AFL may include metal oxides (e.g., titanium oxide (TiOx)), silicon-based compounds, and fluorine-based compounds.

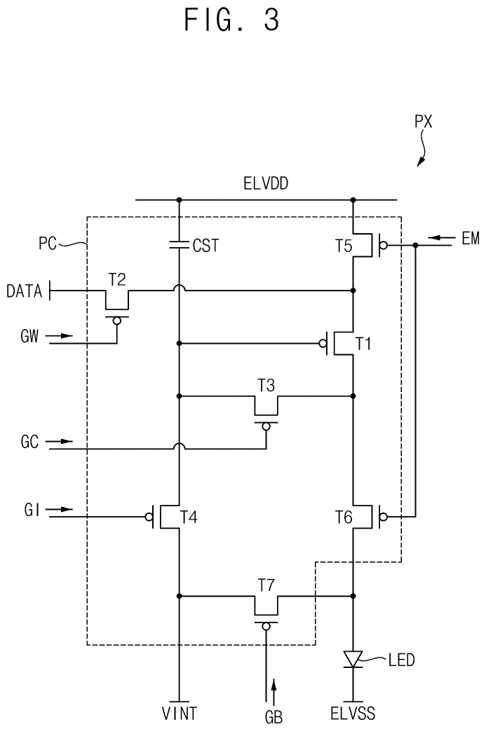

FIG. 2 is a block diagram illustrating a display panel included in the display device of FIG. 1. FIG. 3 is a circuit diagram illustrating a pixel included in the display panel of FIG. 2.

Referring to FIG. 2, the display panel PNL may include a pixel part PXP, a gate driver GDV, a data driver DDV, an emission driver EDV, and a controller CON.

The pixel part PXP may include at least one pixel PX and may be provided with a voltage (e.g., a power voltage and/or a data voltage) for driving the pixel PX. In addition, the pixel part PXP may include a data line DL connected to the pixel PX, a gate line GL connected to the pixel PX, and an emission control line EML.

The gate driver GDV may generate gate signals GW, GC, GI, and GB based on a gate control signal GCTRL. For example, the gate signals GW, GC, GI, and GB may include a gate-on voltage that turns on the transistor and a gate-off voltage that turns off the transistor. The gate control signal GCTRL may include a vertical start signal, a clock signal, etc.

The data driver DDV may generate the data voltage DATA based on an output image data ODAT and a data control signal DCTRL. For example, the data driver DDV may generate the data voltage DATA corresponding to the output image data ODAT and may output the data voltage DATA in response to the data control signal DCTRL. The data control signal DCTRL may include an output data enable signal, a horizontal start signal, and a load signal.

The emission driver EDV may generate an emission control signal EM based on an emission driving signal ECTRL. For example, the emission driving signal ECTRL may include a vertical start signal, a clock signal, etc., and the emission control signal EM may include a gate-on voltage that turns on the transistor and a gate-off voltage that turns off the transistor.

The controller CON (e.g., timing controller (T-CON)) may receive input image data IDAT and a control signal CTRL from an external host processor (e.g., GPU). For example, the input image data IDAT may be RGB data including red image data, green image data, and blue image data. The control signal CTRL may include a vertical synchronization signal, a horizontal synchronization signal, an input data enable signal, and a master clock signal. The controller CON may operate based on the input image data IDAT and the control signal CTRL, and may generate the gate control signal GCTRL, the emission driving signal ECTRL, the data control signal DCTRL, and the output image data (ODAT).

Referring to FIG. 3, the pixel PX may include a pixel circuit PC and a light emitting diode LED. The pixel circuit PC may provide a driving current to the light emitting diode LED, and the light emitting diode LED may generate light based on the driving current. For example, the light emitting diode LED may include an organic light emitting diode (OLED), an inorganic light emitting diode, a nano light emitting diode, etc.

The pixel circuit PC may include a first transistor T1, a second transistor T2, a third transistor T3, a fourth transistor T4, a fifth transistor T5, a sixth transistor T6, a seventh transistor T7, and a storage capacitor CST.

The light emitting diode LED may include a first terminal (e.g., an anode terminal) and a second terminal (e.g., a cathode terminal). The first terminal of the light emitting diode LED may be connected to the sixth transistor T6 and the seventh transistor T7, and the second terminal may be provided with a second power voltage ELVSS. The light emitting diode LED may generate light with a brightness corresponding to the driving current.

The storage capacitor CST may include a first terminal and a second terminal. The first terminal of the storage capacitor CST may be connected to the first transistor T1, and the second terminal of the storage capacitor CST may receive a first power voltage ELVDD. The storage capacitor CST may maintain the voltage level of the gate terminal of the first transistor T1 during the deactivation period of a first gate signal GW.

The first transistor T1 may include a gate terminal, a first terminal, and a second terminal. The gate terminal of the first transistor T1 may be connected to the first terminal of the storage capacitor CST. The first terminal of the first transistor T1 may be connected to the second transistor T2 and may receive the data voltage DATA. The second terminal of the first transistor T1 may be connected to the sixth transistor T6. The first transistor T1 may generate the driving current based on the voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive the first gate signal GW through the gate line GL.

The second transistor T2 may be turned on or off in response to the first gate signal GW. For example, when the second transistor T2 is a P-channel metal-oxide-semiconductor (PMOS) transistor, the second transistor T2 may be turned off when the first gate signal GW has a positive voltage level, and may be turned on when the first gate signal GW has a negative voltage level. The first terminal of the second transistor T2 may receive the data voltage DATA through the data line DL. The second terminal of the second transistor T2 may provide the data voltage DATA to the first terminal of the first transistor T1 during the period in which the second transistor T2 is turned on. For example, the second transistor T2 may be referred to as a switching transistor.

The third transistor T3 may include a gate terminal, a first terminal, and a second terminal. The gate terminal of the third transistor T3 may receive a second gate signal GC. The first terminal of the third transistor T3 may be connected to the second terminal of the first transistor T1. The second terminal of the third transistor T3 may be connected to the gate terminal of the first transistor T1.

The third transistor T3 may be turned on or off in response to the second gate signal GC. For example, when the third transistor T3 is a PMOS transistor, the third transistor T3 may be turned off when the second gate signal GC has a positive voltage level, and may be turned on when the second gate signal GC has a negative voltage level.

During a period in which the third transistor T3 is turned on in response to the second gate signal GC, the third transistor T3 may diode-connect the first transistor T1. Accordingly, the third transistor T3 may compensate for the threshold voltage of the first transistor T1. For example, the third transistor T3 may be referred to as a compensation transistor.

The fourth transistor T4 may include a gate terminal, a first terminal, and a second terminal. The gate terminal of the fourth transistor T4 may receive a third gate signal GI. The first terminal of the fourth transistor T4 may be connected to the gate terminal of the first transistor T1. The second terminal of the fourth transistor T4 may receive the initialization voltage VINT.

The fourth transistor T4 may be turned on or off in response to the third gate signal GI. For example, when the fourth transistor T4 is a PMOS transistor, the fourth transistor T4 may be turned off when the third gate signal GI has a positive voltage level, and may be turned on when the third gate signal GI has a negative voltage level.

During a period in which the fourth transistor T4 is turned on by the third gate signal GI, the initialization voltage VINT may be provided to the gate terminal of the first transistor T1. Accordingly, the fourth transistor T4 may initialize the gate terminal of the first transistor T1 to the initialization voltage VINT. For example, the fourth transistor T4 may be referred to as a gate initialization transistor.

The fifth transistor T5 may include a gate terminal, a first terminal, and a second terminal. The gate terminal of the fifth transistor T5 may receive the emission control signal EM. The first terminal of the fifth transistor T5 may receive the first power voltage ELVDD. The second terminal of the fifth transistor T5 may be connected to the first transistor T1. When the fifth transistor T5 is turned on in response to the emission control signal EM, the fifth transistor T5 may provide the first power voltage ELVDD to the first transistor T1.

The sixth transistor T6 may include a gate terminal, a first terminal, and a second terminal. The gate terminal of the sixth transistor T6 may receive the emission control signal EM. The first terminal of the sixth transistor T6 may be connected to the first transistor T1. The second terminal of the sixth transistor T6 may be connected to the light emitting diode LED. When the sixth transistor T6 is turned on in response to the emission control signal EM, the sixth transistor T6 may provide the driving current to the light emitting diode LED.

The seventh transistor T7 may include a gate terminal, a first terminal, and a second terminal. The gate terminal of the seventh transistor T7 may receive the fourth gate signal GB. The first terminal of the seventh transistor T7 may be connected to the light emitting diode LED. The second terminal of the seventh transistor T7 may receive the initialization voltage VINT.

When the seventh transistor T7 is turned on in response to the fourth gate signal GB, the seventh transistor T7 may provide the initialization voltage VINT to the light emitting diode LED. Accordingly, the seventh transistor T7 may initialize the first terminal of the light emitting diode LED to the initialization voltage VINT. For example, the seventh transistor T7 may be referred to as an anode initialization transistor.

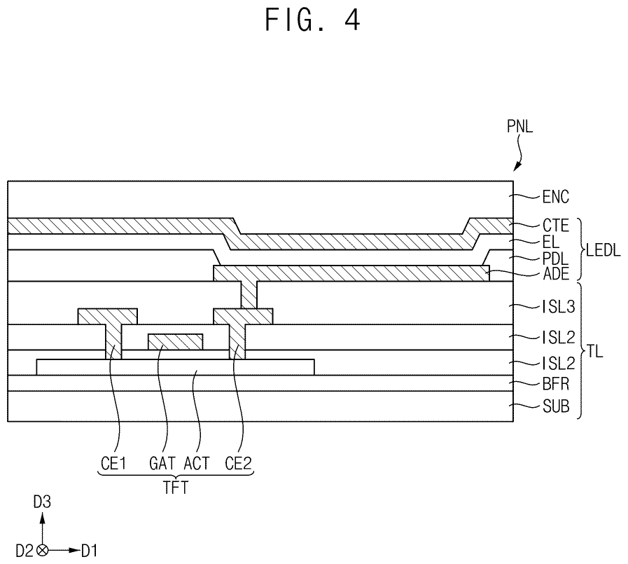

FIG. 4 is a cross-sectional view illustrating the display panel of FIG. 2. Referring to FIG. 4, the display panel PNL may include a transistor layer TL, a light emitting diode layer LEDL, and an encapsulation layer ENC. The transistor layer TL may include a substrate SUB, a buffer layer BFR, an active pattern ACT, a first insulating layer ISL1, a gate electrode GAT, a second insulating layer ISL2, a first connection electrode CE1, a second connection electrode CE2, and a third insulating layer ISL3. The active pattern ACT, the gate electrode GAT, the first connection electrode CE1, and the second connection electrode CE2 may form a transistor TFT. The light emitting diode layer LEDL may include a pixel electrode ADE, a pixel defining layer PDL, an emission layer EL, and a common electrode CTE.

In an embodiment, the substrate SUB may include glass, quartz, plastic, etc. Examples of plastics that can be used in the substrate SUB may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), etc. These can be used alone or in combination with each other.

The buffer layer BFR may be disposed on the substrate SUB. In an embodiment, the buffer layer BFR may include an electrically insulating material. Examples of materials that can be used in the buffer layer BFR may include silicon oxide, silicon nitride, and silicon oxynitride. These can be used alone or in combination with each other.

The active pattern ACT may be disposed on the buffer layer BFR. In an embodiment, the active pattern ACT may include an oxide semiconductor, a silicon semiconductor, or the like.

The first insulating layer ISL1 may be disposed on the buffer layer BFR and may cover the active pattern ACT. In an embodiment, the first insulating layer ISL1 may include an insulating material. Examples of materials that can be used as the first insulating layer ISLI may include silicon oxide, silicon nitride, and silicon oxynitride. These can be used alone or in combination with each other.

The gate electrode GAT may be disposed on the first inorganic insulating layer ISL1 and may overlap the active pattern ACT. In an embodiment, the gate electrode GAT may include a metal, a metal alloy, a conductive metal oxide, a transparent conductive material, etc. Examples of materials that can be used as the gate electrode GAT may include silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These can be used alone or in combination with each other.

The second insulating layer ISL2 may be disposed on the first insulating layer ISL1 and may cover the gate electrode GAT. In an embodiment, the second insulating layer ISL2 may include an electrically insulating material. Examples of materials that can be used as the second insulating layer ISL2 may include silicon oxide, silicon nitride, and silicon oxynitride. These can be used alone or in combination with each other.

The first connection electrode CE1 and the second connection electrode CE2 may be disposed on the second insulating layer ISL2 and may be in contact with the active pattern ACT. In an embodiment, the first connection electrode CE1 and the second connection electrode CE2 may include metal, alloy, conductive metal oxide, transparent conductive material, etc. Examples of materials that can be used as the first connection electrode CE1 and the second connection electrode CE2 may include silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), and indium zinc oxide (IZO). These can be used alone or in combination with each other.

The third insulating layer ISL3 may be disposed on the second insulating layer ISL2 and may cover the first connection electrode CE1 and the second connection electrode CE2. In an embodiment, the third insulating layer ISL3 may include an electrically insulating material. Examples of materials that can be used as the third insulating layer ISL3 may include photoresist, polyacrylic resin, polyimide resin, and acrylic resin. These can be used alone or in combination with each other.

The pixel electrode ADE may be disposed on the third insulating layer ISL3 and may contact the second connection electrode CE2. The pixel defining layer PDL may be disposed on the third insulating layer ISL3 and may include an opening exposing the pixel electrode ADE. The emission layer EL may be disposed on the pixel electrode ADE. The common electrode CTE may be disposed on the emission layer EL.

The encapsulation layer ENC may be disposed on the common electrode CTE. The encapsulation layer ENC may prevent moisture and air from penetrating into the emission layer EL. In an embodiment, the encapsulation layer ENC may have a structure in which an inorganic insulating layer, an organic insulating layer, and an inorganic insulating layer are stacked in that order.

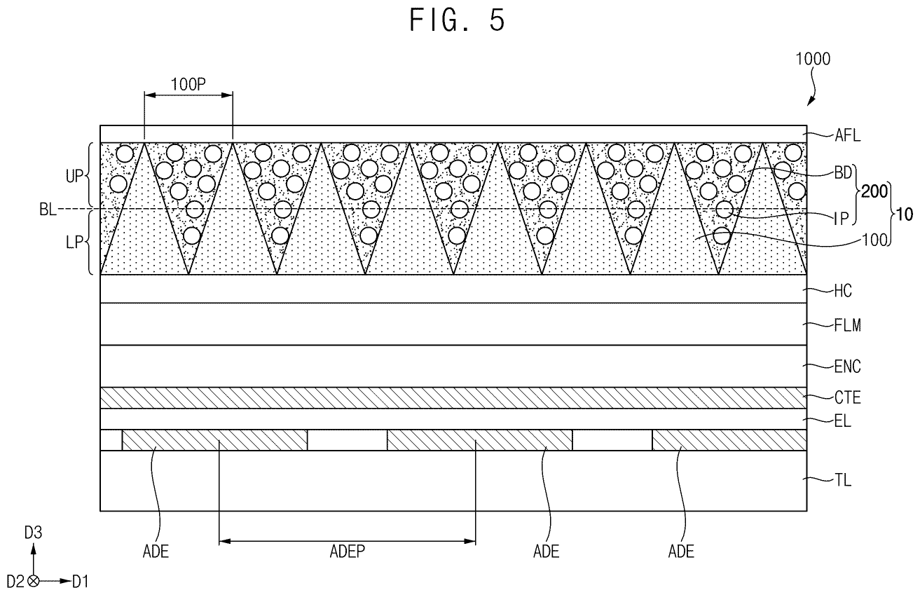

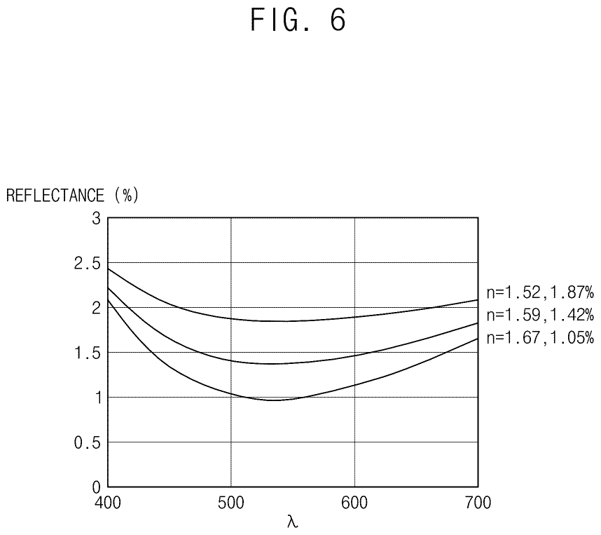

FIG. 5 is a cross-sectional view illustrating the display device of FIG. 1. FIG. 6 is a graph illustrating a reflectance according to a wavelength of light of display device of FIG. 5.

Referring to FIG. 5, the refractive layer 10 may include high refractive index patterns 100 and low refractive index patterns 200. Each of the low refractive patterns 200 may include a binder BD and at least one inorganic particle IP.

The high refractive index patterns 100 may be disposed on the hard coating layer HC. In an embodiment, the high refractive index patterns 100 may be arranged side by side in the first direction D1 and the second direction D2 and may protrude in the third direction D3.

In an embodiment, a bisector line BL that bisects the high refractive index patterns 100 in a thickness direction (e.g., the third direction D3) of the high refractive index patterns 100 may be defined. In this case, the sum of the areas of the high refractive patterns 100 located at a lower part LP of the bisector line BL may be greater than the sum of the areas of the high refractive patterns 100 located at the upper part UP of the bisector line BL.

For example, as shown in FIG. 5, each of the high refractive index patterns 100 may have a triangular shape. In this case, a lower surface of the triangular shape may be disposed adjacent to the window film FLM.

In addition, in an embodiment, as shown in FIG. 5, the high refractive index patterns 100 may contact each other. In an embodiment, the high refractive patterns 100 may be spaced apart from each other.

However, the shape of each of the high refractive patterns 100 is not necessarily limited to the above-described shape. Each of the high refractive index patterns 100 may have an appropriate shape in which the low refractive patterns 200 can be disposed. For example, each high refractive index pattern 100 may have a shape such as a rectangle, diamond, cylinder, etc.

In an embodiment, the high refractive index patterns 100 may have a first refractive index. For example, the first refractive index may be within a range of about 1.5 to about 1.8. In addition, the indentation hardness of the high refractive patterns 100 may be about 500 MPa or more.

In this case, the high refractive index patterns 100 may include organic materials, inorganic materials, etc. that satisfy the above-described conditions. For example, examples of organic materials that can be used as the high refractive patterns 100 may include photoresist, polyacrylic resin, polyimide resin, acrylic resin, epoxy resin, and acrylate resin. Examples of inorganic materials that can be used as the high refractive patterns 100 may include silicon oxide, silicon nitride, and silicon oxynitride. In addition, these can be used alone or in combination with each other.

In an embodiment, the high refractive index patterns 100 may be arranged at a predetermined pitch 100P. Accordingly, the low refractive index patterns 200 may be disposed between the high refractive index patterns 100. For example, when the diameter of the inorganic particle IP is about 500 nm, the pitch 100P between the high refractive index patterns 100 may be about 0.5 μm or more. In addition, the high refractive index patterns 100 may have an irregular shape in which the pitch 100P is within about 0.5 μm to about 2 μm, and thus the Moiré pattern phenomenon may be prevented.

In an embodiment, the pixel electrodes ADE may be arranged side by side in the first direction D1, and a pitch ADEP between the pixel electrodes ADE may be different from the pitch 100P between the high refractive index patterns 100. For example, an emission area and a non-emission area may be defined by the pixel electrodes ADE, and the high refractive index patterns 100 may be arranged without corresponding to the emission area and the non-emission area.

The low refractive index patterns 200 may be disposed on the high refractive index patterns 100 and may be disposed between the high refractive index patterns 100. As described above, the high refractive index patterns 100 may have the pitch 100P corresponding to the diameter of the inorganic particle IP, and the low refractive patterns 200 may be disposed between the high refractive index patterns 100.

In an embodiment, a shape of each of the low refractive index patterns 200 may be set to correspond to a shape of each of the high refractive index patterns 100. For example, when each of the high refractive index patterns 100 has a triangular shape, each of the low refractive index patterns 200 may have a triangular shape.

In an embodiment, the low refractive index patterns 200 may have a second refractive index. The second refractive index may be smaller than the first refractive index. For example, the second refractive index may be within a range of about 1.3 to about 1.5.

The low refractive index patterns 200 may include the binder BD and the inorganic particle IP.

The binder BD may include a material in which the inorganic particle IP are dispersed, and may include, for example, an acrylic compound, a urethane-based compound, a siloxane-based compound, an imide-based compound, and/or an epoxy-based compound. For example, the binder BD may be polyacrylic resin, polyurethane resin, polysiloxane resin, polyimide resin, and/or polyepoxy resin.

In an embodiment, the refractive index of the binder BD may be greater than the second refractive index. For example, the difference between the first refractive index and the refractive index of the binder BD may be less than the difference between the first refractive index and the second refractive index. For example, the refractive index of the binder BD may be similar to the first refractive index. Accordingly, optical interference might not occur in the process of refraction and reflection of external light, and the display quality of the display device 1000 may be increased.

The inorganic particle IP may include a material that satisfies the second refractive index together with the binder BD. For example, the inorganic particle IP may include a hollow silica particle, titanium oxide (TiO₂), aluminum oxide (Al₂O₃), indium oxide (In₂O₃), zinc oxide (ZnO), etc.

Referring to FIG. 6, the refractive index of a top surface of the refractive layer 10 was fixed at 1.4, the refractive index of a bottom surface of the refractive layer 10 was adjusted, and the reflectance of the display device 1000 was measured. In the graph shown in FIG. 6, the X-axis represents the wavelength of external light, the Y-axis represents the reflectance of the display device, and n represents the refractive index of the bottom surface of the refractive layer 10.

When the refractive index of the bottom surface was about 1.67, the reflectance was measured to be about 1.05%. When the refractive index of the bottom surface was about 1.59, the reflectance was measured to be about 1.42%. When the refractive index of the bottom surface was about 1.52, the reflectance was measured to be about 1.87%.

As the display device 1000 includes the refractive layer 10, the reflectance of the display device 1000 was measured to be about 1% to 2%, and it was confirmed that it had a significantly lower reflectance compared to conventional display devices. In addition, it was confirmed that as the difference between the refractive index of the bottom surface and the refractive index of the top surface increases, the reflectance decreases. Therefore, by adjusting the difference between the refractive index of the bottom surface and the refractive index of the top surface, the reflectance can be adjusted to a target setting value.

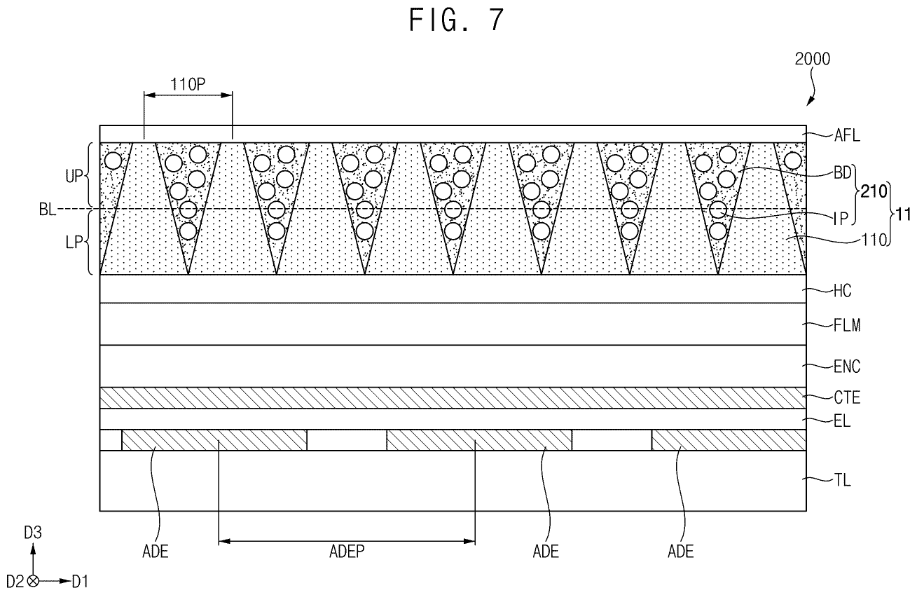

FIG. 7 is a cross-sectional view illustrating a display device according to an embodiment of the present invention.

Referring to FIG. 7, a display device 2000 according to an embodiment of the present invention may include a transistor layer TL, a pixel electrode ADE, an emission layer EL, a common electrode CTE, an encapsulation layer ENC, a window film (FLM), a hard coating layer HC, a refractive layer 11, and an anti-fingerprint layer AFL. However, the display device 2000 may be substantially the same as the display device 1000 described above with reference to FIG. 5, except for the refractive layer 11.

The refractive layer 11 may include high refractive index patterns 110 and low refractive index patterns 210. Each of the low refractive index patterns 210 may include a binder BD and at least one inorganic particle IP.

The high refractive index patterns 110 may be disposed on the hard coating layer HC. In an embodiment, the high refractive index patterns 110 may be arranged side by side in the first direction D1 and the second direction D2 and may protrude in the third direction D3.

In an embodiment, a bisector line BL that bisects the high refractive index patterns 110 in a thickness direction (e.g., the third direction D3) of the high refractive index patterns 110 may be defined. In this case, the sum of the areas of the high refractive patterns 110 located at a lower part LP of the bisector line BL may be greater than the sum of the areas of the high refractive patterns 110 located at the upper part UP of the bisector line BL.

For example, as shown in FIG. 7, each of the high refractive index patterns 110 may have a trapezoidal shape. In this case, the length of the lower surface of the trapezoidal shape may be longer than the length of the upper surface of the trapezoidal shape, and the lower surface may be disposed adjacent to the window film FLM.

In addition, in an embodiment, as shown in FIG. 7, the high refractive index patterns 110 may contact each other.

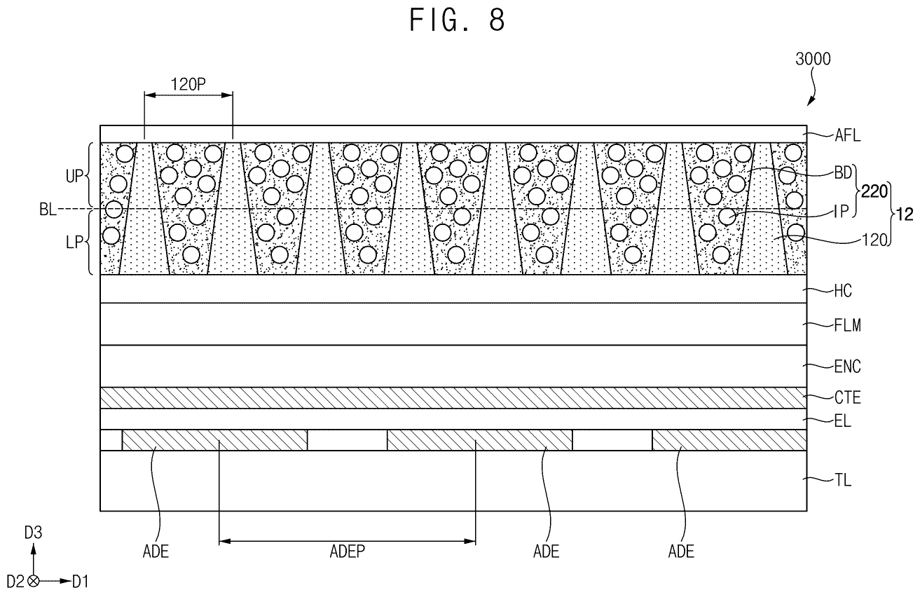

In an embodiment, as shown in FIG. 8, the high refractive patterns 120 may be spaced apart from each other.

Referring again to FIG. 7, in an embodiment, the high refractive index patterns 110 may have a first refractive index. For example, the first refractive index may be within a range of about 1.5 to about 1.8. In addition, the indentation hardness of the high refractive index patterns 110 may be about 500 MPa or more.

In this case, the high refractive index patterns 110 may include organic materials, inorganic materials, etc. that satisfy the above-described conditions. For example, examples of organic materials that can be used as the high refractive index patterns 110 may include photoresist, polyacrylic resin, polyimide resin, acrylic resin, epoxy resin, and acrylate resin. Examples of inorganic materials that can be used as the high refractive patterns 110 may include silicon oxide, silicon nitride, and silicon oxynitride. In addition, these can be used alone or in combination with each other.

In an embodiment, the high refractive index patterns 110 may be arranged at predetermined pitch 110P. Accordingly, the low refractive index patterns 210 may be disposed between the high refractive index patterns 110. For example, when the diameter of the inorganic particle IP is about 500 nm, the pitch 110P between the high refractive patterns 110 may be about 0.5 μm or more. In addition, the high refractive index patterns 110 may have an irregular shape where the pitch 110P is within about 0.5 μm to about 2 μm, and thus the Moiré pattern phenomenon may be prevented.

In an embodiment, the pixel electrodes ADE may be arranged side by side in the first direction D1, and a pitch ADEP between the pixel electrodes ADE may be different from the pitch 110P between the high refractive index patterns 110. For example, an emission area and a non-emission area may be defined by the pixel electrodes ADE, and the high refractive index patterns 110 may be arranged without corresponding to the emission area and the non-emission area.

The low refractive index patterns 210 may be disposed on the high refractive index patterns 110 and may be disposed between the high refractive index patterns 110. As described above, the high refractive index patterns 110 may have the pitch 110P corresponding to the diameter of the inorganic particle IP, and the low refractive index patterns 210 may be disposed between the high refractive index patterns 110.

In an embodiment, a shape of each of the low refractive index patterns 210 may be set to correspond to a shape of each of the high refractive index patterns 110. For example, as shown in FIG. 7, when each of the high refractive index patterns 110 has a trapezoidal shape adjacent to each other, each of the low refractive patterns 210 may have a triangular shape.

In an embodiment, the low refractive index patterns 210 may have a second refractive index. The second refractive index may be smaller than the first refractive index. For example, the second refractive index may be within a range of about 1.3 to about 1.5.

FIG. 8 is a cross-sectional view illustrating a display device according to still an embodiment of the present invention.

Referring to FIG. 8, a display device 3000, according to an embodiment of the present invention, may include a transistor layer TL, a pixel electrode ADE, an emission layer EL, a common electrode CTE, an encapsulation layer ENC, a window film FLM, a hard coating layer HC, a refractive layer 12, and an anti-fingerprint layer AFL. However, the display device 3000 may be substantially the same as the display device 1000 described above with reference to FIG. 5, except for the refractive layer 12.

The refractive layer 12 may include high refractive index patterns 120 and low refractive index patterns 220. Each of the low refractive patterns 220 may include a binder BD and at least one inorganic particle IP.

The high refractive index patterns 120 may be disposed on the hard coating layer HC. In an embodiment, the high refractive index patterns 120 may be arranged side by side along the first direction D1 and the second direction D2 and may protrude in the third direction D3.

In an embodiment, a bisector line BL that bisects the high refractive index patterns 120 in a thickness direction (e.g., the third direction D3) of the high refractive index patterns 120 may be defined. In this case, the sum of the areas of the high refractive patterns 120 located at a lower part LP of the bisector line BL may be greater than the sum of the areas of the high refractive patterns 120 located at the upper part UP of the bisector line BL.

For example, as shown in FIG. 8, each of the high refractive index patterns 120 may have a trapezoidal shape. In this case, the length of the lower surface of the trapezoidal shape may be longer than the length of the upper surface of the trapezoidal shape, and the lower surface may be disposed adjacent to the window film FLM.

In addition, in an embodiment, as shown in FIG. 8, the high refractive index patterns 120 may be spaced apart from each other.

In an embodiment, the high refractive index patterns 120 may have a first refractive index. For example, the first refractive index may be within a range of about 1.5 to about 1.8. In addition, the indentation hardness of the high refractive index patterns 120 may be about 500 MPa or more.

In this case, the high refractive index patterns 120 may include organic materials, inorganic materials, etc. that satisfy the above-described conditions. For example, examples of organic materials that can be used as the high refractive index patterns 120 may include photoresist, polyacrylic resin, polyimide resin, acrylic resin, epoxy resin, and acrylate resin. Examples of inorganic materials that can be used as the high refractive index patterns 120 may include silicon oxide, silicon nitride, and silicon oxynitride. Additionally, these can be used alone or in combination with each other.

In an embodiment, the high refractive index patterns 120 may be arranged at predetermined pitch 120P. Accordingly, the low refractive index patterns 220 may be disposed between the high refractive index patterns 120. For example, when the diameter of the inorganic particle IP is about 500 nm, the pitch 120P between the high refractive index patterns 120 may be about 0.5 μm or more. In addition, the high refractive index patterns 120 may have an irregular shape where the pitch 120P is within about 0.5 μm to about 2 μm, and thus the Moiré pattern phenomenon may be prevented.

In an embodiment, the pixel electrodes ADE may be arranged side by side in the first direction D1, and a pitch ADEP between the pixel electrodes ADE may be different from the pitch 120P between the high refractive index patterns 120. For example, an emission area and a non-emission area may be defined by the pixel electrodes ADE, and the high refractive patterns 120 may be arranged without corresponding to the emission area and the non-emission area.

The low refractive index patterns 220 may be disposed on the high refractive index patterns 120 and may be disposed between the high refractive index patterns 120. As described above, the high refractive index patterns 120 may have the pitch 120P corresponding to the diameter of the inorganic particle IP, and the low refractive index patterns 220 may be disposed between the high refractive index patterns 120.

In an embodiment, a shape of each of the low refractive index patterns 220 may be set to correspond to a shape of each of the high refractive index patterns 120. For example, as shown in FIG. 8, when each of the high refractive index patterns 120 has a trapezoidal shape spaced apart from each other, each of the low refractive patterns 220 may have a trapezoidal shape.

In an embodiment, the low refractive index patterns 220 may have a second refractive index. The second refractive index may be smaller than the first refractive index. For example, the second refractive index may be within a range of about 1.3 to about 1.5.

Display devices, according to embodiments of the present invention, may include a refractive layer. The refractive layer may be disposed on a window film and may include high refractive index patterns and low refractive index patterns. The high refractive index patterns may have a shape that protrudes from the window film, and the low refractive patterns may be disposed between the high refractive index patterns. As the high refractive index patterns have a predetermined indentation hardness, durability of the refractive layer can be increased. In addition, as each of the high refractive index patterns and the low refractive patterns has a predetermined refractive index, the reflectance of the display device may be reduced.

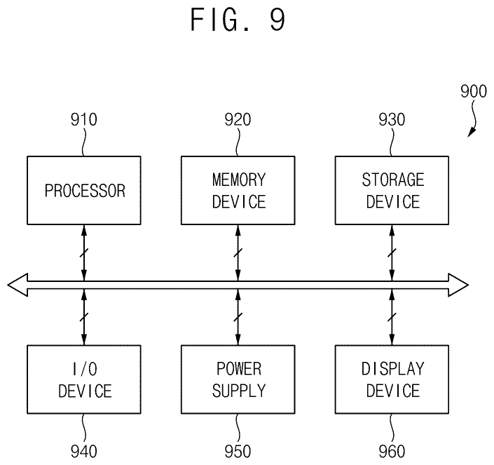

FIG. 9 is a block diagram illustrating an electronic device according to an embodiment.

Referring to FIG. 9, in an embodiment, an electronic device 900 may include a processor 910, a memory device 920, a storage device 930, an input/output (“I/O”) device 940, a power supply 950, and a display device 960. Here, the display device 960 may correspond to the display device 1000 of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although certain embodiments and implementations have been described herein, other embodiments and modifications will be apparent from this description. Accordingly, the inventive concepts are not necessarily limited to such embodiments, but rather to the broader scope of the appended claims and various obvious modifications and equivalent arrangements as would be apparent to a person of ordinary skill in the art.

What is claimed is:

1. A window module, comprising:
a window film;
high refractive index patterns disposed on the window film, each of the high refractive index patterns having a first refractive index, and being arranged side by side; and
low refractive index patterns disposed between neighboring pairs of the high refractive index patterns, each of the low refractive index patterns having a second refractive index that is smaller than the first refractive index.

2. The window module of claim 1, wherein the first refractive index is within a range of about 1.5 to about 1.8, and
wherein the second refractive index is within a range of about 1.3 to about 1.5.

3. The window module of claim 1, wherein each of the low refractive index patterns includes:
a binder; and
an inorganic particle dispersed within the binder.

4. The window module of claim 3, wherein a refractive index of the binder is greater than the second refractive index.

5. The window module of claim 3, wherein a difference between the first refractive index and a refractive index of the binder is less than a difference between the first refractive index and the second refractive index.

6. The window module of claim 3, wherein the inorganic particle is a hollow silica particle.

7. The window module of claim 1, wherein a pitch between neighboring pairs of the high refractive patterns is about 0.5 μm or more.

8. The window module of claim 1, wherein a bisector line bisecting the high refractive index patterns in a thickness direction thereof is defined, and
wherein a sum of areas of the high refractive patterns located at a lower part of the bisector line is greater than a sum of areas of the high refractive patterns located at an upper part of the bisector line.

9. The window module of claim 1, wherein a shape of each of the high refractive index patterns is triangular.

10. The window module of claim 9, wherein a lower surface of the triangular shape is disposed adjacent to the window film.

11. The window module of claim 1, wherein a shape of each of the high refractive index patterns is trapezoidal.

12. The window module of claim 11, wherein a length of a lower surface of the trapezoidal shape is longer than a length of an upper surface of the trapezoidal shape, and
wherein the lower surface of the trapezoidal shape is disposed adjacent to the window film.

13. The window module of claim 11, wherein the high refractive index patterns contact each other.

14. The window module of claim 11, wherein the high refractive index patterns are spaced apart from each other.

15. An electronic device, comprising:
a display panel; and
a window module disposed on the display panel,
wherein the window module includes:
a window film;
high refractive index patterns disposed on the window film, each of the high refractive index patterns having a first refractive index, and being arranged side by side; and
low refractive index patterns disposed between neighboring pairs of the high refractive index patterns and each having a second refractive index that is smaller than the first refractive index.

16. The electronic device of claim 15, wherein the display panel includes pixel electrodes arranged side by side, and
wherein a pitch between the pixel electrodes is different from a pitch between the high refractive index patterns.

17. The electronic device of claim 15, wherein the first refractive index is within a range of about 1.5 to about 1.8, and
wherein the second refractive index is within a range of about 1.3 to about 1.5.

18. The electronic device of claim 15, wherein each of the low refractive index patterns includes:
a binder; and
an inorganic particle dispersed within the binder.

19. The electronic device of claim 18, wherein a refractive index of the binder is greater than the second refractive index, and
wherein a difference between the first refractive index and a refractive index of the binder is less than a difference between the first refractive index and the second refractive index.

20. The electronic device of claim 15, wherein a bisector line bisecting the high refractive index patterns in a thickness direction thereof is defined, and
wherein a sum of areas of the high refractive patterns located at a lower part of the bisector line is greater than a sum of areas of the high refractive patterns located at an upper part of the bisector line.
